(19) United States
(12) Patent Application Publication
(10) Pub. No.: US 2008/0017856 A1
(43) Pub. Date: Jan. 24, 2008

(54) Wafer and semiconductor device testing method

(75) Inventor: Hiroaki Fujino, Kizugawa-shi (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 11/819,035

(22) Filed: Jun. 25, 2007

(30) Foreign Application Priority Data
Jul. 13, 2006 (JP) 2006-192868

(51) Int. Cl. H01L 23/58; G01R 31/26

(52) U.S. Cl. 257/48; 324/765; 257/E21.521

(57) ABSTRACT

At least three pads 10A, 10B, 10C are provided on a scribe line 8 located adjacent to a chip region 2. The three pads are a power pad 10A connected to a power potential portion 5 in the chip region 2, a grounding pad 10B connected to a ground potential portion 6 in the chip region 2, and a switchover pad 10C that is connected to a semiconductor device 7 in the chip region 2 and switches the operating state of the semiconductor device 7 between a normal operating state and a standby state. During a wafer test, contact pins 9A, 9B, 9C of a probe card are brought in contact with the three pads 10A, 10B, 10C, respectively.

### CROSS-REFERENCE TO RELATED APPLICATIONS

This Nonprovisional application claims priority under 35 U.S.C. §119(a) on Patent Application No. 2006-192868 filed in Japan on Jul. 13, 2006, the entire contents of which are hereby incorporated by reference.

### BACKGROUND OF THE INVENTION

The present invention relates to a wafer, and in particular, to a wafer in which semiconductor devices are fabricated in chip regions, respectively.

The present invention further relates to a testing method of the semiconductor devices fabricated on such a wafer.

As shown in FIG. 2A, in a general wafer 101 that has undergone a wafer process, a wafer surface is segmented into a plurality of rectangular regions (referred to as “chip regions”) 102, and a semiconductor device (not shown) is fabricated in each of the chip regions 102. As shown in FIG. 2B (a part 103 in FIG. 2A is shown enlarged), the chip regions 102 are partitioned by a scribe line (also referred to as a dicing line) 108 that has a certain width. A plurality of pads 104 for inputting and outputting signals between the elements inside the chip regions and the outside are arranged in peripheral portions (portions along the scribe line 108) of the chip regions 102. During a wafer test, contact pins 109, 109, . . . of a preparatorily produced probe card are brought in contact with all pads 104, 104, . . . inside the chip regions 102 to test the electric characteristics of the semiconductor devices in the chip regions 102.

The wafer is divided into chips, and thereafter only the chips that have been determined to be nondefective products in the wafer test stage are each assembled into a package or the like. The assembled products are subjected to a shipping test, and only the products that have been determined to be nondefective products through the shipping test are shipped.

Conventionally, for example, JP 2002-184825 A discloses a technique for placing test pads in prescribed positions inside each of the chip regions 102 so that one probe card can be used in common for a plurality of kinds of semiconductor products. Moreover, JP 2002-184825 A also discloses a technique for placing the test pads on the dicing lines 108 for the purpose of preventing the chip size (area of the chip region) from increasing.

Moreover, JP H5-299484 A discloses a technique for providing test pads with which the contact pins of the probe card are brought in contact on the scribe lines of a wafer for the purpose of facilitating the probing while keeping the area of the chip region (integrated circuit forming section).

Moreover, JP 2004-342725 A discloses a technique for providing test pads with which the contact pins of the probe card are brought in contact on the scribe lines of a wafer for the purpose of carrying out a test without damaging the pads in the chip regions. Moreover, the document also discloses a technique for sharing the test pads on a scribe line in mutually adjacent chip regions so that the test pads can be reduced in number by half.

### SUMMARY OF THE INVENTION

However, the above patent documents provide neither description nor suggestion regarding the reductions in the number of the test pads and the contact pins of the probe card by reducing the number of test signals. Accordingly, there is a room for improvement.

An object of the present invention is to provide a wafer and a semiconductor device testing method capable of reducing the number of the test pads and the contact pins of the probe card by reducing the number of test signals, using a common probe card for different models of products and therefore achieving a cost reduction.

In order to achieve the object, the present invention provides a wafer on which a plurality of chip regions in each of which a semiconductor device is fabricated are partitioned by scribe lines, the wafer comprising:

at least three pads, which are provided on the scribe line located adjacent to the chip region and with which contact pins of a probe card are brought in contact,

the three pads being a power pad connected to a power potential portion in the chip region, a grounding pad connected to a ground potential portion in the chip region, and a switchover pad that is connected to the semiconductor device in the chip region and switches an operating state of the semiconductor device between a normal operating state and a standby state.

In this case, the “standby state” means a state in which the semiconductor device is at rest, and the consumption current becomes approximately zero when the semiconductor device is a nondefective product. The “normal operating state” broadly indicates operating states other than the standby state.

In the wafer of the present invention, it is determined whether each semiconductor device in the wafer is nondefective or defective as follows. First of all, the first, second and third contact pins are brought in contact with the corresponding three pads on the scribe line located adjacent to a certain chip region, i.e., the power pad, the grounding pad and the switchover pad, respectively. Then, by giving predetermined signals from the contact pins of the probe card, the power potential portion in the chip region is maintained at the power potential through the power pad, and the ground potential portion in the chip region is maintained at the ground potential through the grounding pad. Concurrently, the operating state of the semiconductor device in the chip region is maintained in the standby state through the switchover pad. It is determined whether the semiconductor device is nondefective or defective on the basis of the value of a current (leakage current) that flows between the power pad and the grounding pad in the standby state. It is noted that another signal is given from the third contact pin of the probe card in order to put the operating state of the semiconductor device in the chip region into the normal operating state.

When it is determined whether each of the semiconductor devices in the wafer is nondefective or defective as described above, it is only necessary to provide three contact pins for the probe card, and therefore, the test pads and the contact pins of the probe card can be reduced in number. Moreover, if the three contact pins are arranged at predetermined intervals and in a predetermined order in correspondence with the three pads, a common probe card can be used even if the product model is varied. Therefore, a cost reduction can be achieved.

In one embodiment of the wafer, the three pads are connected to only one chip region located adjacent to the scribe line on which the pads are provided.

In one embodiment of the wafer, the three pads are connected to a plurality of chip regions located adjacent to the scribe line on which the pads are provided.

According to the present one embodiment of the wafer, the semiconductor devices in the plurality of chip regions can be tested by bringing the contact pins of the probe card in contact with the three pads one time. Therefore, the time for the test is shortened with regard to the entire wafer.

In one embodiment of the wafer, the switchover pad is constituted in common with the power pad.

According to the present one embodiment of the wafer, the test pads and the contact pins of the probe card can further be reduced in number.

In order to achieve the object, the present invention provides a semiconductor device testing method for testing electrical characteristics of each of semiconductor devices of an objective wafer on which a plurality of chip regions in each of which a semiconductor device is fabricated are partitioned by scribe lines,

the wafer comprising:

at least three pads provided on a scribe line located adjacent to the chip region,

the three pads being a power pad connected to a power potential portion in the chip region, a grounding pad connected to a ground potential portion in the chip region, and a switchover pad that is connected to the semiconductor device in the chip region and switches an operating state of the semiconductor device between a normal operating state and a standby state,

the method comprising the steps of:

bringing first, second and third contact pins of a probe card in contact with corresponding power pad, grounding pad and switchover pad, respectively, on the scribe line located adjacent to a certain chip region;

maintaining a power potential portion in the chip region at a power potential via the power pad, maintaining a ground potential portion in the chip region at a ground potential via the grounding pad and maintaining an operating state of the semiconductor device in the chip region in the standby state via the switchover pad by giving predetermined signals from the contact pins of the probe card, respectively; and

determining whether the semiconductor device is nondefective or defective on the basis of a value of a current that flows between the power pad and the grounding pad in the standby state.

According to the semiconductor device testing method of the present invention, first of all, the first, second and third contact pins are brought in contact with the corresponding three pads on the scribe line located adjacent to a certain chip region, i.e., the power pad, the grounding pad and the switchover pad, respectively. Then, by giving predetermined signals from the contact pins of the probe card, the power potential portion in the chip region is maintained at the power potential through the power pad, and the ground potential portion in the chip region is maintained at the ground potential through the grounding pad. Concurrently, the operating state of the semiconductor device in the chip region is maintained in the standby state through the switchover pad. It is determined whether the semiconductor device is nondefective or defective on the basis of the value of a current (leakage current) that flows between the power pad and the grounding pad in the standby state. It is noted that another signal is given from the third contact pin of the probe card in order to put the operating state of the semiconductor device in the chip region into the normal operating state.

When it is determined whether each of the semiconductor devices in the wafer is nondefective or defective as described above, the probe card is only necessary to have three contact pins, and therefore, the test signals can be reduced in number. Therefore, the test pads and the contact pins of the probe card can be reduced in number. Moreover, if the three contact pins are arranged at predetermined intervals and in a predetermined order in correspondence with the three pads, a common probe card can be used even if the product model is varied. Therefore, a cost reduction can be achieved.

In one embodiment of the semiconductor device testing method, the three pads are connected to only one chip region located adjacent to the scribe line on which the pads are provided.

In one embodiment of the semiconductor device testing method, the three pads are connected to a plurality of chip regions located adjacent to the scribe line on which the pads are provided.

According to the present one embodiment the semiconductor device testing method, the semiconductor devices in the plurality of chip regions can be tested by bringing the contact pins of the probe card in contact with the three pads one time. Therefore, the time for the test is shortened with regard to the entire wafer.

In one embodiment of the semiconductor device testing method, the switchover pad is constituted in common with the power pad.

According to the present one embodiment of the semiconductor device testing method, the test pads and the contact pins of the probe card can further be reduced in number.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A is a view showing the schematic construction of a wafer according to one embodiment of the present invention;

FIG. 1B is a view showing a testing method according to one embodiment of the present invention with the wafer shown in FIG. 1A partially enlarged;

FIG. 2A is a view showing the schematic construction of a conventional wafer; and

FIG. 2B is a view showing a conventional testing method with the wafer shown in FIG. 2A partially enlarged.

### DETAILED DESCRIPTION OF THE INVENTION

The present invention will be described in detail below by the embodiment shown in the drawings.

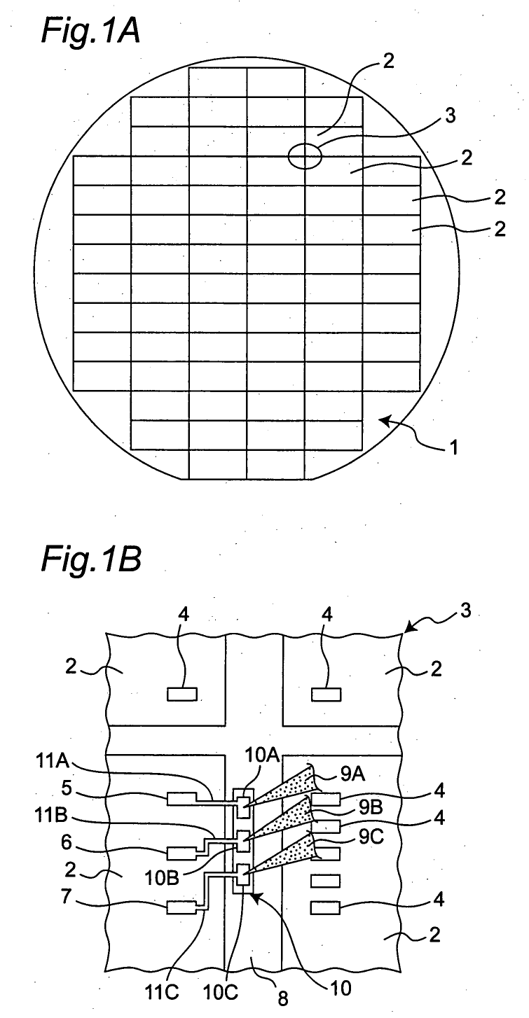

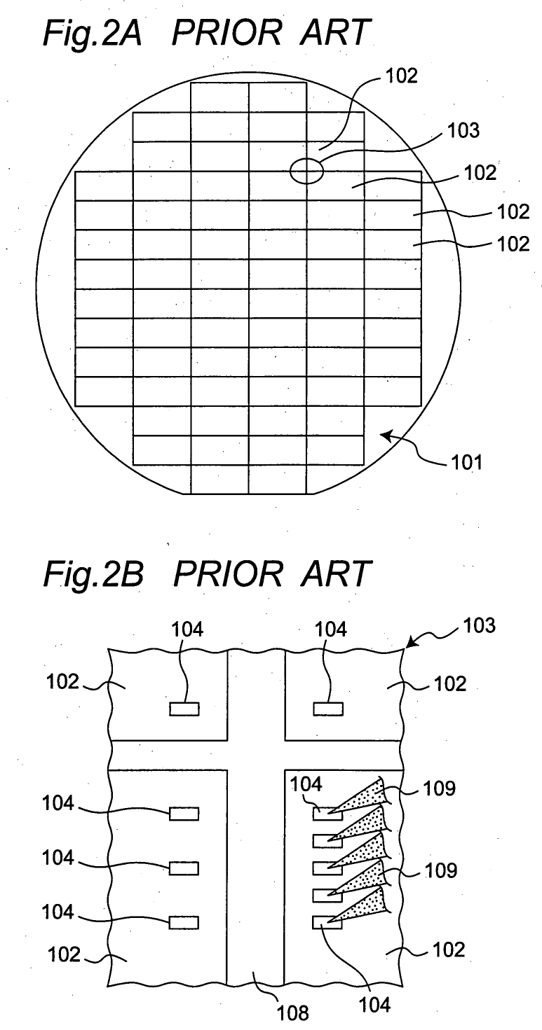

FIG. 1A shows the schematic construction of a wafer 1 according to one embodiment of the present invention. The wafer 1 has undergone a wafer process, and the wafer surface is segmented into a plurality of rectangular regions (referred to as “chip regions”) 2 as in a general wafer. A semiconductor device (not shown) is fabricated in each of the chip regions 2.

FIG. 1B shows a part of FIG. 1A, i.e., a portion 3 where corner portions of four chip regions 2 gather. As shown in FIG. 1B, the chip regions 2 are partitioned by a scribe line (also referred to as a dicing line) 8 that has a certain width between the chip regions. It is noted that the wafer 1 is segmented into chips along the scribe line 8 after finishing a wafer test described later. A plurality of pads 4 for inputting and outputting signals between the elements in the chip regions and the outside are arranged in peripheral portions (portions along the scribe line 8) of the chip regions 2.

An upper right-hand peripheral portion of each chip region 2 (the upper right-hand peripheral portion of the lower left-hand chip region 2 is illustrated in FIG. 1B) has a power potential portion 5 to which a power potential for the semiconductor device fabricated in the chip region 2 in operation is given, a ground potential portion 6 to which a ground potential (0 V) is given, and a switch 7 as a switchover portion. Moreover, a pad region 10 including three pads 10A, 10B, 10C is provided along the scribe line 8 located adjacent to the chip region 2.

The three pads are a power pad 10A connected to the power potential portion 5 in the chip region 2 via an interconnection 11A, a grounding pad 10B connected to the ground potential portion 6 in the chip region 2 via an interconnection 11B, and a switchover pad 10C connected to the switchover portion 7 of the semiconductor device in the chip region 2 via an interconnection 11C. In this example, the pads 10A, 10B, 10C are patterned into rectangular regions and arranged at a constant pitch in the vertical direction (in FIG. 1B).

In this example, by giving a predetermined control signal in a switchover manner to the switch 7 in the chip region 2 via the switchover pad 10C and the interconnection 11C, the operating state of the semiconductor device in the chip region 2 can be switched over between a normal operating state and a standby state.

During the wafer test, it is determined whether each of the semiconductor devices in the wafer 1 is nondefective or defective as follows.

First of all, first, second and third contact pins 9A, 9B and 9C of the probe card are brought in contact with the corresponding power pad 10A, grounding pad 10B and switchover pad 10C on the scribe line 8 located adjacent to a certain chip region (the lower left-hand chip region 2 in FIG. 1B). It is noted that the probe card has a card main body (not shown) and three metallic contact pins 9A, 9B, 9C projecting from the card main body.

Then, by giving predetermined signals from the contact pins 9A, 9B, 9C of the probe card, the power potential portion 5 in the chip region 2 is maintained at the power potential via the power pad 10A and the interconnection 11A, and the ground potential portion 6 in the chip region 2 is maintained at the ground potential via the grounding pad 10B and the interconnection 11B. Concurrently, the operating state of the semiconductor device in the chip region 2 is maintained in the standby state via the switchover pad 10C and the interconnection 11C. It is determined whether the semiconductor device is nondefective or defective on the basis of the value of a current (leakage current) that flows between the power pad 10A and the grounding pad 10B in the standby state. For example, when the semiconductor device is a nondefective product, the leakage current in the standby state becomes approximately zero. Therefore, by setting the upper limit value of the leakage current to, for example, 1 μA, it can be determined that the semiconductor device is nondefective when the leakage current is smaller than 1 μA or it is defective when the leakage current is not smaller than 1 μA.

In order to put the operating state of the semiconductor device in chip region 2 into the normal operating state, another control signal is given from the third contact pin 9C of the probe card.

When it is determined whether each of the semiconductor devices in the wafer 1 is nondefective or defective as described above, it is only necessary to provide three contact pins 9A, 9B, 9C for the probe card, and therefore, the test signals can be reduced in number. Therefore, the test pads and the contact pins of the probe card can be reduced in number. Moreover, if the three contact pins 9A, 9B, 9C are arranged at predetermined intervals and in a predetermined order in correspondence with the three pads 10A, 10B, 10C, a common probe card can be used even if the product model is varied. Therefore, a cost reduction can be achieved.

In this example, the three pads 10A, 10B, 10C on the scribe line 8 are connected to only one chip region (the lower left-hand chip region in FIG. 1B) 2 located adjacent to the scribe line 8. Therefore, the test can be performed successively for each of the chip regions 2 on the wafer 1 in an identical procedure. Therefore, operation for the test is allowed to be simple.

Since the chip size is generally varied depending on each model of the semiconductor device, the interval of the scribe lines 8 is also varied. However, a general wafer tester has a specification such that the pitch of moving the wafer in the transverse direction and the longitudinal direction can be set by being electrically varied. Therefore, when the model of the semiconductor device is varied, it is only necessary to electrically change the pitch. Since the change in the pitch is not a mechanical change that requires replacement of the probe card, almost no time loss occurs at the time of changing the model.

Moreover, the three pads 10A, 10B, 10C on the scribe line 8 may be connected to a plurality of (e.g., two) chip regions 2 located adjacent to the scribe line 8. In this case, by bringing the contact pins 9A, 9B, 9C of the probe card in contact with the three pads 10A, 10B, 10C one time, the semiconductor devices in the plurality of chip regions 2 can be tested. Therefore, the time for the test can be shortened with regard to the entire wafer.

Moreover, if the specifications of the semiconductor device permit, it is acceptable to further reduce the number of the contact pins of the probe card by constituting the switchover pad 10C in common with the power pad 10A.

The interconnections 11A, 11B, 11C for the connection of the three pads 10A, 10B, 10C on the scribe line 8 to the inside of the chip region 2 should desirably be metal interconnections of a small resistance. It can be considered a case where the cross sections of the interconnections 11A, 11B, 11C are exposed when the wafer 1 is divided into chips. In the case of metal interconnections, it is possible that rust or the like might be generated by being coupled with the moisture in the air. Therefore, the interconnections 11A, 11B, 11C, in particular portions to expose cross sections of them should desirably be made of polysilicon or the like so that rust or the like is not generated.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A wafer on which a plurality of chip regions in each of which a semiconductor device is fabricated are partitioned by scribe lines, the wafer comprising:
at least three pads, which are provided on the scribe line located adjacent to the chip region and with which contact pins of a probe card are brought in contact,
the three pads being a power pad connected to a power potential portion in the chip region, a grounding pad connected to a ground potential portion in the chip region, and a switchover pad that is connected to the semiconductor device in the chip region and switches an operating state of the semiconductor device between a normal operating state and a standby state.

2. The wafer as claimed in claim 1, wherein
the three pads are connected to only one chip region located adjacent to the scribe line on which the pads are provided.

3. The wafer as claimed in claim 1, wherein
the three pads are connected to a plurality of chip regions located adjacent to the scribe line on which the pads are provided.

4. The wafer as claimed in claim 1, wherein
the switchover pad is constituted in common with the power pad.

5. A semiconductor device testing method for testing electrical characteristics of each of semiconductor devices of an objective wafer on which a plurality of chip regions in each of which a semiconductor device is fabricated are partitioned by scribe lines,
the wafer comprising:
at least three pads provided on a scribe line located adjacent to the chip region,
the three pads being a power pad connected to a power potential portion in the chip region, a grounding pad connected to a ground potential portion in the chip region, and a switchover pad that is connected to the semiconductor device in the chip region and switches an operating state of the semiconductor device between a normal operating state and a standby state,
the method comprising the steps of:
bringing first, second and third contact pins of a probe card in contact with corresponding power pad, grounding pad and switchover pad, respectively, on the scribe line located adjacent to a certain chip region;
maintaining a power potential portion in the chip region at a power potential via the power pad, maintaining a ground potential portion in the chip region at a ground potential via the grounding pad and maintaining an operating state of the semiconductor device in the chip region in the standby state via the switchover pad by giving predetermined signals from the contact pins of the probe card, respectively; and
determining whether the semiconductor device is nondefective or defective on the basis of a value of a current that flows between the power pad and the grounding pad in the standby state.

6. The semiconductor device testing method as claimed in claim 5, wherein
the three pads are connected to only one chip region located adjacent to the scribe line on which the pads are provided.

7. The semiconductor device testing method as claimed in claim 5, wherein
the three pads are connected to a plurality of chip regions located adjacent to the scribe line on which the pads are provided.

8. The semiconductor device testing method as claimed in claim 5, wherein
the switchover pad is constituted in common with the power pad.
